(19) United States
(12) Patent Application Publication
(10) Pub. No.: US 2023/0055921 A1
(43) Pub. Date: Feb. 23, 2023

(54) SEMICONDUCTOR PACKAGE AND METHOD OF FABRICATING THE SAME

(71) Applicant: Samsung Electronics Co., Ltd., Suwon-si (KR)

(72) Inventor: Min Keun KWAK, Asan-si (KR)

(21) Appl. No.: 17/720,793

(22) Filed: Apr. 14, 2022

(30) Foreign Application Priority Data
Aug. 19, 2021 (KR) 10-2021-0109592

(51) Int. Cl. H01L 23/498; H01L 23/31; H01L 23/00; H01L 21/56; H01L 21/48

(52) U.S. Cl. CPC H01L 23/49822; H01L 23/3128; H01L 23/49811; H01L 24/08; H01L 21/568; H01L 21/4857; H01L 2224/08235; H01L 2224/05647; H01L 2224/05655; H01L 2224/05664; H01L 2224/05669; H01L 2224/05644; H01L 2224/05657; H01L 24/05

(57) ABSTRACT

A semiconductor package includes: a wiring structure including at least one wiring layer; a semiconductor chip disposed on the wiring structure and connected to the wiring structure; a connecting terminal formed on a first surface of the wiring structure; a support member spaced apart from the wiring structure; a dummy connecting terminal formed on a first surface of the support member; and a mold layer covering a side surface of the wiring structure, a first surface of the semiconductor chip, and a second surface and a side surface of the support member.

### CROSS-REFERENCE TO RELATED APPLICATION

This application claims priority under 35 U.S.C. § 119 to Korean Patent Application No. 10-2021-0109592 filed on Aug. 19, 2021 in the Korean Intellectual Property Office, the disclosure of which is incorporated by reference herein in its entirety.

### TECHNICAL FIELD

The present inventive concept relates to a semiconductor package and a method of fabricating the same.

### DISCUSSION OF THE RELATED ART

Due to development of electronic industry, demands for higher functionality, higher speed and increased miniaturization of electronic components have increased. In response to such demands, a method of stacking and mounting a plurality of semiconductor chips on a single package wiring structure or a method of stacking multiple packages on each other has been under development.

As a kind of packaging technology, there is a wafer level package that utilizes the redistribution or rerouting of a bonding pad of the semiconductor chips formed on the wafer. Generally, the wafer level package that utilize rerouting has a structural feature in which the bonding pad on the semiconductor substrate is rerouted to another pad of a larger size in a semiconductor element fabricating process, and then an external connecting terminal such as a solder ball is formed on the package.

Further, the semiconductor package fabricated by such a packaging technology may be divided into a fan-in semiconductor package and a fan-out semiconductor package depending on the structure and application. In the case of a semiconductor chip, a size of the connecting pad and an interval between the connecting pads may be very fine. In addition, in the case of a main board being used for electronic components, the size of each component mounting pad and the interval between component mounting pads are much larger than the scale of the semiconductor chip. Therefore, it may be difficult to mount the semiconductor chip directly on the main board, and a packaging technology that may alleviate or reduce a difference in circuit width may be desirable.

In addition, when the semiconductor chip is mounted on the main board using such a wafer level package, a stress may be concentrated on the solder ball due to a difference in coefficients of thermal expansion (CTE) between the main board and the package, and the reliability of the board level may be degraded.

### SUMMARY

According to an exemplary embodiment of the present inventive concept, a semiconductor package includes: a wiring structure including at least one wiring layer; a semiconductor chip disposed on the wiring structure and connected to the wiring structure; a connecting terminal formed on a first surface of the wiring structure; a support member spaced apart from the wiring structure; a dummy connecting terminal formed on a first surface of the support member; and a mold layer covering a side surface of the wiring structure, a first surface of the semiconductor chip, and a second surface and a side surface of the support member.

According to an exemplary embodiment of the present inventive concept, a semiconductor package includes: a wiring structure including at least one wiring layer; a support member connected to a dummy connecting terminal and having a cavity, wherein the wiring structure is disposed in the cavity and is spaced apart from an inner surface of the cavity; a semiconductor chip connected to the wiring structure and disposed in the cavity; and a mold layer filling the cavity, wherein the dummy connecting terminal and the semiconductor chip are not electrically connected to each other.

According to an exemplary embodiment of the present inventive concept, a method for fabricating a semiconductor package includes: forming a support member on a substrate, wherein an adhesive layer and a first conductive pattern are formed on the substrate; etching at least a part of the support member to form a cavity; forming a wiring structure and a semiconductor chip in the cavity, wherein a second conductive pattern is formed in the wiring structure, and the semiconductor chip is disposed on the wiring structure; forming a mold layer on a side surface and an upper surface of the semiconductor chip; removing the adhesive layer; and forming a connecting terminal and a dummy connecting terminal on one surface of the wiring structure and one surface of the first conductive pattern, respectively, exposed by removing the adhesive layer.

### BRIEF DESCRIPTION OF THE DRAWINGS

The above and other features of the present inventive concept will become more apparent by describing in detail exemplary embodiments thereof with reference to the attached drawings, in which:

FIGS. 1 and 2 are diagrams illustrating an electronic device according to an exemplary embodiment of the present inventive concept;

FIG. 3 is a diagram illustrating a semiconductor package and a main board of FIG. 2;

FIG. 4 illustrates a layout diagram of the semiconductor package according to an exemplary embodiment of the present inventive concept of FIG. 3;

FIG. 5 is a schematic cross-sectional view of the semiconductor package taken along I-I′ of FIG. 4 according to an exemplary embodiment of the present inventive concept;

FIG. 6 illustrates a layout diagram of a semiconductor package according to an exemplary embodiment of the present inventive concept of FIG. 3;

FIG. 7 is a schematic cross-sectional view of a semiconductor package taken along II-II′ of FIG. 4 according to an exemplary embodiment of the present inventive concept: and

FIGS. 8a, 8b, 8c, 8d, 8e, 9, 10, 11, 12, 13, and 14 are diagrams for illustrating a method for fabricating a semiconductor package according to an exemplary embodiment of the present inventive concept.

### DETAILED DESCRIPTION OF THE EMBODIMENTS

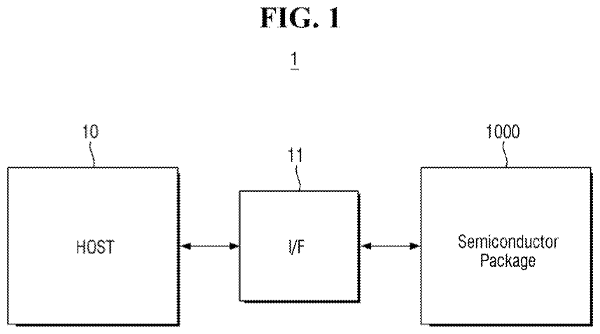

Hereinafter, a semiconductor package according to an exemplary embodiment of the present inventive concept will be described with reference to FIGS. 1 to 5.

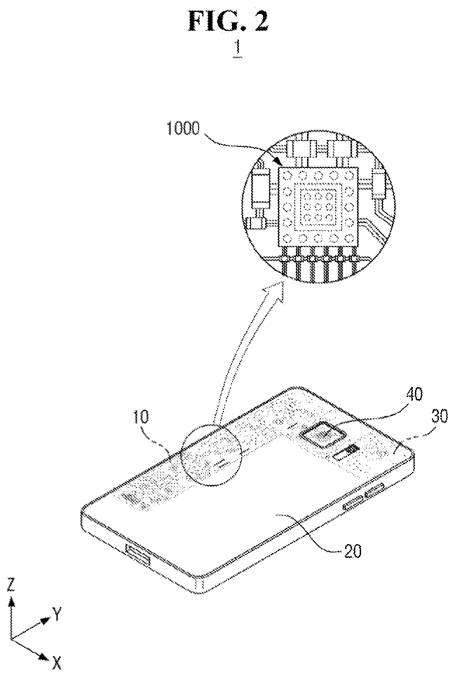

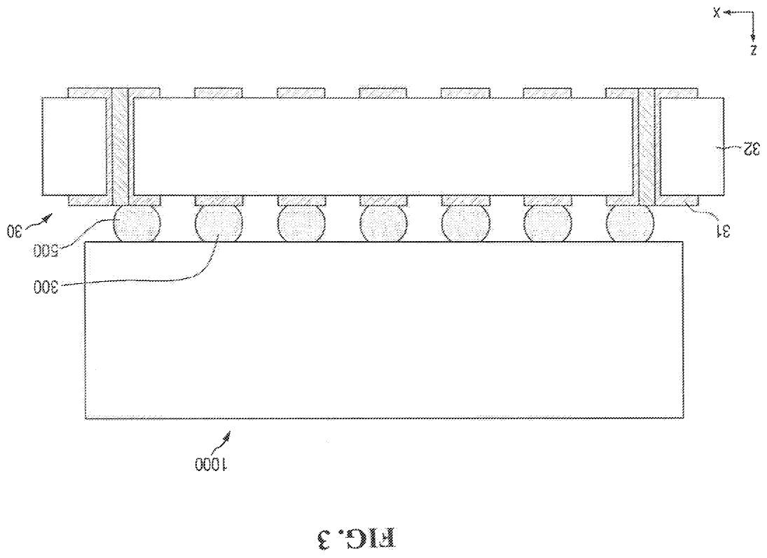

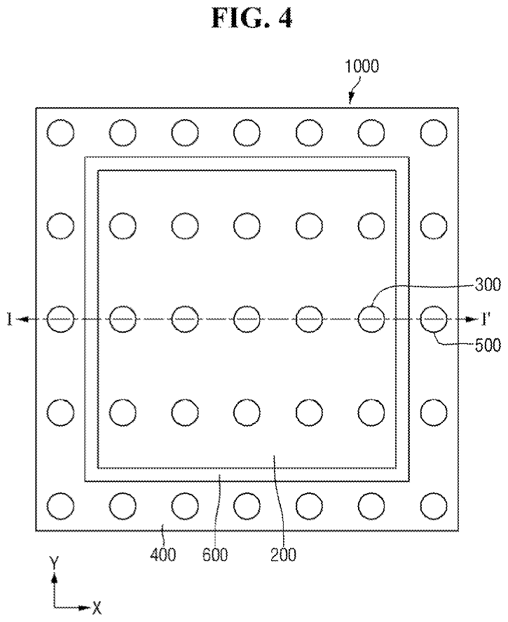

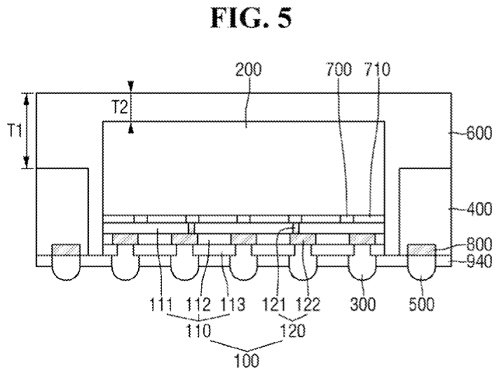

FIGS. 1 and 2 are diagrams illustrating an electronic device according to an exemplary embodiment of the present inventive concept. FIG. 3 is a diagram illustrating a semiconductor package and a main board of FIG. 2. FIG. 4 illustrates a layout diagram of the semiconductor package according to an exemplary embodiment of the present inventive concept of FIG. 3. FIG. 5 is a schematic cross-sectional view of the semiconductor package taken along I-I′ of FIG. 4 according to an exemplary embodiment of the present inventive concept.

Referring to FIG. 1, the electronic device 1 may include a host 10, an interface 11, and a semiconductor package 1000.

In an exemplary embodiment of the present inventive concept, the host 10 may be connected to the semiconductor package 1000 through the interface 11. For example, through the interface 11, the host 10 may transmit a signal to the semiconductor package 1000 to control the semiconductor package 1000. Further, for example, the host 10 may receive a signal from the semiconductor package 1000 through the interface 11 and process the data included in the signal.

For example, the host 10 may include a central processing unit (CPU), a controller an application specific integrated circuit (ASIC), and the like. Further, for example, the host 10 may include memory chips such as a DRAM (Dynamic Random Access Memory), a SRAM (Static RAM), a PRAM (Phase-change RAM), a MRAM (Magneto resistive RAM), a FeRAM (Ferroelectric RAM), and a RRAM (Resistive RAM).

Referring to FIGS. 1 and 2, the electronic device 1 may include a host 10, a body 20, a main board 30, a camera module 40, and a semiconductor package 1000.

The main board 30 may be mounted inside the body 20 of the electronic device 1. The host 10, the camera module 40, and the semiconductor package 1000 may be mounted on the main board 30. The host 10, the camera module 40, and the semiconductor package 1000 may be electrically connected to each other by the main board 30. For example, the interface 11 may be implemented by the main board 30.

The host 10 and the semiconductor package 1000 are electrically connected to each other by the main board 30 and may send and receive signals.

Referring to FIG. 3, the semiconductor package 1000 may be placed on the main board 30. For example, the connecting terminal 300 may be placed on the main board 30. The main board 30 may be connected to the semiconductor package 1000 through the connecting terminal 300.

The main board 30 may be, for example, a printed circuit wiring structure (e.g., a printed circuit board (PCB)), a ceramic wiring structure, a glass wiring structure, an interposer wiring structure, or the like. However, the present inventive concept is not limited thereto.

The main board 30 may include a connecting structure 31 and a core 32. The core 32 may include, for example, a CCL (Copper Clad Laminate), a photoplethysmogram (PPG), an ABF (Ajimoto Build-up Film), epoxy, polyimide and the like. For example, the connecting structure 31 may include, but is not limited to, at least one of copper (Cu), aluminum (Al), silver (Ag), tin (Sn), gold (Au), nickel (Ni), lead (Pb), titanium (Ti), and alloys thereof.

The core 32 is placed at a central part of the main board 30, and the connecting structure 31 may be placed above and below the core 32. The connecting structure 31 may be placed to be exposed above and below the main board 30. For example, the wiring structure 31 may extend along the side surfaces of the core 32.

Further, the connecting structure 31 may be placed to penetrate the core 32. The connecting structure 31 may electrically connect elements that come into contact with the main board 30 to each other. For example, the connecting structure 31 may electrically connect the semiconductor package 1000 and the host 10 to each other. For example, the connecting structure 31 may electrically connect the semiconductor package 1000 and the host 10 to each other through the first connecting terminal 300.

Referring to FIGS. 4 and 5, the semiconductor package according to an exemplary embodiment of the present inventive concept includes a wiring structure 100, a semiconductor chip 200, a connecting terminal 300, a support member 400, a dummy connecting terminal 500, a mold layer 600, and connecting pads 700 and 800.

The wiring structure 100 may be a wiring structure for packaging. For example, the wiring structure 100 may be a printed circuit wiring structure (e.g., a printed circuit board (PCB)), a ceramic wiring structure, or the like. The wiring structure 100 may be a wiring structure for a wafer level package (WLP) fabricated at a wafer level. The wiring structure 100 may include a lower side and an upper side that are opposite to each other.

The wiring structure 100 includes an insulating layer 110 and a wiring layer 120. The insulating layer 110 may include a first insulating layer 111, a second insulating layer 112, and a third insulating layer 113 which are sequentially placed between the semiconductor chip 200 and the connecting structure 300. The wiring layer 120 may include a wiring via 121 and a wiring pad 122 that are placed between the semiconductor chip 200 and the connecting terminal 300. For example, the wiring via 121 may be disposed on the wiring pad 122.

The insulating layer 110 of the wiring structure 100 may include, for example, a printed circuit board (PCB) or a ceramic substrate. However, the present inventive concept is not limited thereto.

When the insulating layer 110 is a printed circuit board, the insulating layer 110 may be made of at least one of, for example, phenol resin, epoxy resin, and/or polyimide. For example, the insulating layer 110 may include at least one of ABF (Ajimoto Build-up Film), FR-4, tetrafunctional epoxy, polyphenylene ether, epoxy/polypheny oxide, BT (bismaleimide triazine), thermount, cyanate ester, polyimide, and/or liquid crystal polymer.

A surface of the insulating layer 110 may be covered with a solder resist. In an exemplary embodiment of the present inventive concept, a protective film 940, which will be described below, may be the solder resist. However. the present inventive concept is not limited thereto.

In an exemplary embodiment of the present inventive concept, although the insulating layer 110 and the wiring layer 120 of the wiring structure 100 are shown as three layers and two layers, respectively, this is for convenience of explanation, and the number of layers of the insulating layer 110 and the wiring layer 120 is not limited to thereto.

The first insulating layer 111 and the third insulating layer 113 are formed at an uppermost part and a lowermost part of the insulating layer 110, respectively. The first insulating layer 111 may cover the upper surface of the second insulating layer 112 and expose the wiring via 121. For example, the wiring via 121 may penetrate the first insulating layer 111. The third insulating layer 113 may cover the lower surface of the second insulating layer 112 and expose at least a portion of the wiring pad 122.

One surface of the semiconductor chip 200 may be placed on one side of the wiring structure 100. For example, the semiconductor chip 200 may be placed on the wiring structure 100. For example, the semiconductor chip 200 may be mounted on the upper surface of the wiring structure 100.

The semiconductor chip 200 may be an integrated circuit (IC) in which hundreds to millions or more of semiconductor elements are integrated inside a single chip. For example, the semiconductor chip 200 may be, but is not limited to, an application processor (AP), such as a CPU (Central Processing Unit), a GPU (Graphic Processing Unit), an FPGA (Field-Programmable Gate Array), a digital signal processor, an encryption processor, a microprocessor, and a micro controller. For example, the semiconductor chip 200 may be a logic chip such as an ADC (Analog-Digital Converter) or an ASIC (Application-Specific IC), and may be a memory chip such as a volatile memory (e.g., a DRAM) or a non-volatile memory (e.g., a ROM or a flash memory). For example, the semiconductor chip 200 may be configured by combining these elements with each other.

Although only one semiconductor chip 200 is shown as being formed on the wiring structure 100, this is merely for convenience of explanation, and the present inventive concept is not limited thereto. For example, a plurality of semiconductor chips 200 may be formed side by side on the wiring structure 100, or a plurality of semiconductor chips 200 may be sequentially stacked on each other on the wiring structure 100.

In this case, the semiconductor chip 200 may include a first semiconductor chip and a second semiconductor chip stacked on the first semiconductor chip. The first semiconductor chip may include a first substrate on which the first semiconductor element is placed. The second semiconductor chip may include a second substrate on which the second semiconductor element is placed.

The second semiconductor chip and the first semiconductor chip may be electrically connected to each other, by a conductive structure penetrating the first substrate. For example, the conductive structure may be in the form of a post or a via with a cylindrical shape filled with copper (e.g., a Cu post). However, the form of the conductive structure is not limited thereto.

For example, an insulating layer may be formed between the lower surface of the second substrate and the upper surface of the first substrate, and at least one or more coupling pads may be formed inside the insulating layer. The coupling pad may be coupled to the conductive structure to electrically connect the first semiconductor chip and the second semiconductor chip to each other.

In an exemplary embodiment of the present inventive concept, the semiconductor chip 200 may be mounted on the wiring structure 100 by a flip chip bonding method. For example, at least one or more connecting pads 700 may be formed between the upper surface of the wiring structure 100 and the lower surface of the semiconductor chip 200. The connecting pad 700 may electrically connect the wiring structure 100 and the semiconductor chip 200 to each other.

The second semiconductor chip may be electrically connected to the wiring structure 100 through the coupling pad, the conductive structure, and the connecting pad 700.

Referring to FIG. 5, the wiring structure 100 does not include the wiring layer 120 that extends from a region in which the wiring structure 100 overlaps the semiconductor chip 200 to a region in which the wiring structure 100 does not overlap the semiconductor chip 200. For example, the wiring layer 120 does not include a portion that is exposed by the semiconductor chip 200. In this case, the side surface of the semiconductor chip 200 and the side surface of the wiring structure 100 may be connected to each other and may be aligned with each other. In this case, for example, at least one of the plurality of connecting terminals 300 may be placed in the fan-in region. Therefore, the semiconductor package 1000 may be a fan-in semiconductor package.

The connecting terminal 300 may be formed on the lower surface of the wiring structure 100. For example, the wiring structure 100 may include a first side (e.g., a lower surface) and a second side (e.g., an upper surface) opposite to the first side, and the connecting terminal 300 may be formed on the first side. The connecting terminal 300 may be electrically connected to the wiring pad 122. For example, the connecting terminal 300 may penetrate the first insulating layer 111 to be connected to the wiring pad 122.

The shape of the connecting terminal 300 may be, for example, but is not limited to, a spherical shape or an elliptical spherical shape. Although the connecting terminal 300 may include, for example, at least one of tin (Sn), indium (In), lead (Pb), zinc (Zn), nickel (Ni), gold (Au), silver (Ag), copper (Cu), antimony (Sb), bismuth (Bi), and combinations thereof, the present inventive concept is not limited thereto.

The connecting terminal 300 may electrically connect the wiring structure 100 to an external device. Accordingly, the connecting terminal 300 may provide an electric signal to the wiring structure 100, or may provide an electric signal, which is provided from the wiring structure 100, to an external device.

The support member 400 may be placed adjacent to the side surface of the semiconductor chip 200 and the side surface of the wiring structure 100, and may be placed to be spaced apart from each of the side surface of the semiconductor chip 200 and the side surface of the wiring structure 100. Each of the side surface of the semiconductor chip 200 and the side surface of the wiring structure 100 may be at least partially surrounded by the support member 400 with a mold layer 600 to be described later interposed therebetween.

As will be described later, the support member 400 may be formed with a cavity C, and may be spaced apart from the wiring structure 100. In this case, the semiconductor chip 200 may be disposed in at least one region of the cavity C. The mold layer 600 may be filled in the remaining region of the cavity C in which the semiconductor chip 200 and wiring structure 100 are not placed.

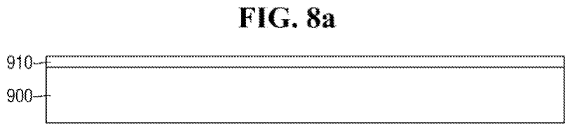

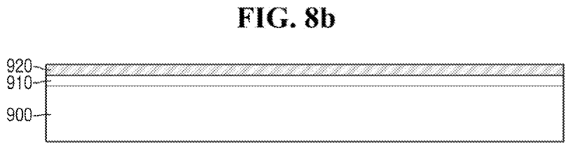

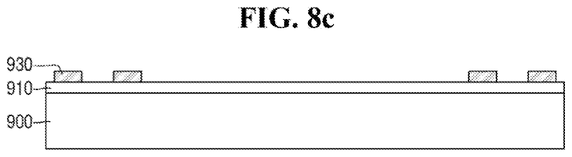

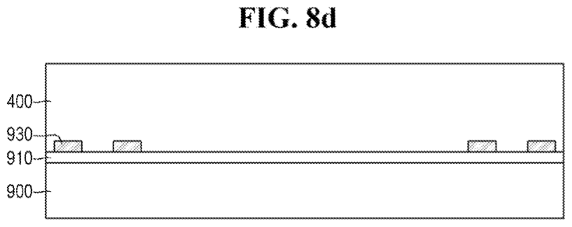

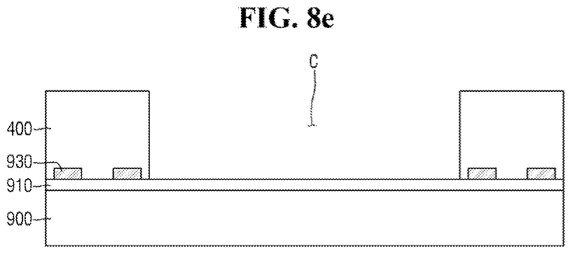

The support member 400 is connected to the dummy connecting terminal 500. The connecting pad 800 is formed inside the support member 400, and may connect the support member 400 and the dummy connecting terminal 500 to each other. As will be described later, the connecting pad 800 may be a conductive pattern formed by etching a copper foil layer 920 formed on one surface of the substrate 900 (see, e.g., FIGS. 8b and 8c). The connecting pad 800 may include a conductive material.

The support member 400 may include an organic material. For example, the support member 400 may include a polymeric material that may reduce a difference in coefficients of thermal expansion between the main board 30 and the semiconductor chip 200. However, the present inventive concept is not limited to thereto.

The support member 400 may reduce the difference in coefficients of thermal expansion between the main board 30 and the semiconductor chip 200. Further, by placing a separate support member 400 outside the semiconductor chip 200, it is possible to provide a semiconductor package that is not easily damaged even when an external force is applied.

The dummy connecting terminal 500 is formed on one side of the support member 400. The support member 400 may include a first side facing the main board 30, and a second side opposite to the first side. The dummy connecting terminal 500 may be placed on the main board 30.

The dummy connecting terminal 500 and the semiconductor chip 200 are not electrically connected to each other. In this case, the dummy connecting terminal 500 and the wiring structure 100 are not electrically connected to each other. For example, the dummy connecting terminal 500 and the connecting pad 700 are not electrically connected to each other.

The shape of the dummy connecting terminal 500 may be, for example, but is not limited to, a spherical shape or an elliptical spherical shape. The dummy connecting terminal 500 may include, for example, at least one of tin (Sn), indium (In), lead (Pb), zinc (Zn), nickel (Ni), gold (Au), silver (Ag), copper (Cu), antimony (Sb), bismuth (Bi), and combinations thereof. However, the present inventive concept is not limited thereto.

In a comparative example, due to the difference in coefficients of thermal expansion between the main board 30 and the semiconductor chip 200, a phenomenon in which a stress is concentrated on the connecting terminal 300 placed in the outermost portion of the semiconductor chip 200 may occur.

In an exemplary embodiment of the present inventive concept, the support member 400 is placed on the outermost portion of the semiconductor chip 200, and a dummy connecting terminal 500 that has an electrical path different from that of the connecting terminal 300 may be formed on the support member 400.

As a result, when the semiconductor package 1000 is mounted on the main board 30, the stress applied to the dummy connecting terminal 500 may be greater than the stress applied to the connecting terminal 300. Accordingly, the problem in which stress is concentrated on the connecting terminal 300 can be reduced, and the board level reliability of the semiconductor package 1000 can be increased.

The mold layer 600 may be disposed on the semiconductor chip 200 and the support member 400. For example, the mold layer 600 may cover the side surface of the wiring structure 100, the upper surface and the side surface of the semiconductor chip 200, and the upper surface and the side surface of the support member 400.

A thickness T1 of the mold layer 600 formed on the upper surface of the support member 400 may be thicker than a thickness T2 of the mold layer 600 formed on the upper surface of the semiconductor chip 200. However, the present inventive concept is not limited thereto.

The mold layer 600 may include, for example, an insulating polymer material such as EMC (epoxy molding compound). The mold layer 600 includes a thermosetting resin such as an epoxy resin, a thermoplastic resin such as polyimide, or a resin in which a reinforcing material such as a filler is included in them, for example, ABF, FR-4, BT resin and the like.

The filler may utilize at least one or more of silica (SiO₂), alumina (Al₂O₃), silicon carbide (SiC), barium sulfate (BaSO₄), talc, mud, mica powder, aluminum hydroxide (Al(OH)₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), and/or calcium zirconate (CaZrO₃). However, the material of the filler is not limited thereto.

In the case of the wafer level package, according to a comparative example, since the surface of the semiconductor chip 200 may be exposed, a corner portion of the semiconductor chip 200 may be damaged by an external force.

On the other hand, in an exemplary embodiment of the present inventive concept, because the support member 400 covers the side surface of the semiconductor chip 200 and the mold layer 600 covers the upper surface of the semiconductor chip 200, it is possible to reduce or prevent damage to the semiconductor chip 200.

The connecting pad 700 is formed on one surface of the semiconductor chip 200 that faces one side (e.g., an upper surface) of the wiring structure 100. The connecting pad 700 may protrude from the lower surface of the semiconductor chip 200. The connecting pad 700 may include, for example, but is not limited to, copper (Cu), copper alloy, nickel (Ni), palladium (Pd), platinum (Pt), gold (Au), cobalt (Co) and combinations thereof.

An insulating film 710 may be disposed on the lower surface of the semiconductor chip 200 and may expose the connecting pad 700. The insulating film 710 may be, for example, an oxide film, a nitride film, or the like. In addition, the insulating film 710 may be a multi-layer (e.g., a double layer) of an oxide film and a nitride film.

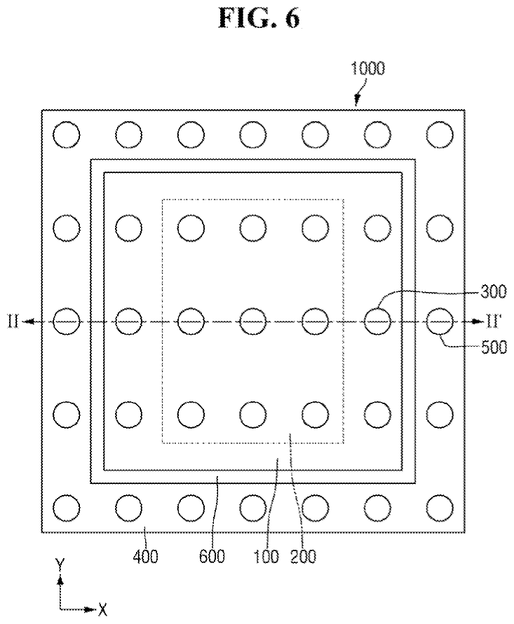

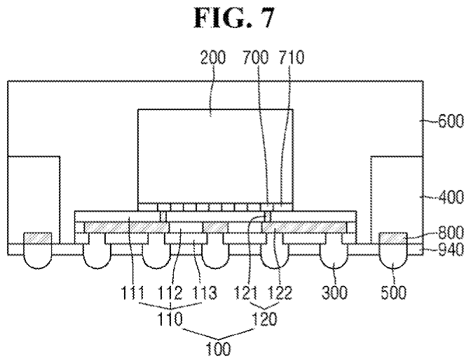

Hereinafter, a semiconductor package according to an exemplary embodiment of the present inventive concept will be described with reference to FIGS. 6 and 7. For convenience of explanation, differences from the semiconductor package shown in FIGS. 1 to 5 will be mainly described. In addition, to the extent that the description of various elements are omitted, it may be assumed that these elements are at least similar to corresponding elements that have already been described.

FIG. 6 illustrates a layout diagram of a semiconductor package according to an exemplary embodiment of the present inventive concept of FIG. 3. FIG. 7 is a schematic cross-sectional view of a semiconductor package taken along II-II′ of FIG. 4 according to an exemplary embodiment of the present inventive concept.

Referring to FIG. 6, the wiring layer 120 includes a wiring pad 122 that extends from a region, in which the wiring layer 120 overlaps the semiconductor chip 200, to a region, in which wiring layer does not overlap the semiconductor chip 200. For example, a portion of the wiring pad 122 may be overlapped by the semiconductor chip 200, while another portion of the wiring pad 122 might not be overlapped by the semiconductor chip 200.

In this case, at least one of the plurality of connecting terminals 300 may be placed in the fan-out region. Therefore, the semiconductor package 1000 may be a fan-out semiconductor package.

In this case, the mold layer 600 may cover the upper surface of the wiring structure 100 exposed by the semiconductor chip 200. For example, the mold layer 600 my directly contact the upper surface of the wiring structure 100 exposed by the semiconductor chip 200.

FIGS. 8a, 8b, 8c, 8d, 8e, 9, 10, 11, 12, 13, and 14 are diagrams illustrating a method for fabricating a semiconductor package according to an exemplary embodiment of the present inventive concept.

Referring to FIG. 8a, an adhesive layer 910 is formed on one surface of the substrate 900. The substrate 900 may be, but is not limited to, CCL (Copper clad Laminate), PPG (Prepreg), or the like. For example, the adhesive layer 910 may be a tape or the like. For example, the adhesive layer 910 may include an ultraviolet curable adhesive tape, which has an adhesive strength that is weakened by ultraviolet rays, a heat-treated curable adhesive tape, which has an adhesive strength that is weakened by heat treatment, or the like.

Referring to FIG. 8b, a copper foil layer 920 is formed on the adhesive layer 910. The copper foil layer 920 may be formed of a thin copper (Cu) film.

Referring to FIG. 8c, the copper foil layer 920 is etched to form a conductive pattern 930. The copper foil layer 920 may be etched to have a pattern shape, using a mask placed on the substrate 900. For example, the conductive pattern 930 may include openings. In this case, the adhesive layer 910 is not etched, and the copper foil layer 920 may be formed to be selectively etched.

Referring to FIG. 8d, the support member 400 is formed over the conductive pattern 930 and the adhesive layer 910. The support member 400 may be formed to cover the upper surface and at least one side surface of the conductive pattern 930. and the upper surface of the adhesive layer 910.

Referring to FIG. 8e, at least a part of the support member 400 is etched to form a cavity C. For example, the cavity C may be formed, by irradiating at least a part of the support member 400 with a laser, or using a mask placed on the support member 400. However, the present inventive concept is not limited thereto.

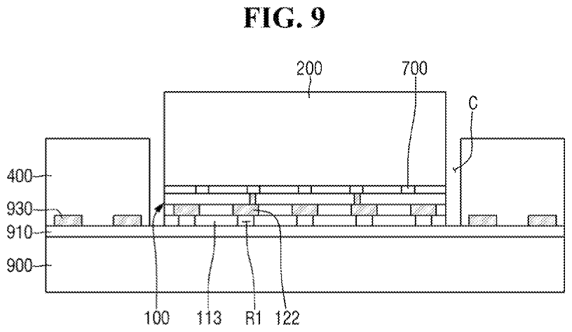

Referring to FIG. 9, the wiring structure 100, which includes the wiring layer 120, and the semiconductor chip 200 are placed inside the cavity C. In an exemplary embodiment of the present inventive concept, the semiconductor chip 200, on which the wiring structure 100 is formed, may be fabricated in advance, and then the semiconductor chip 200 may be disposed inside the cavity C. Although the method of attaching the wiring structure 100 to the semiconductor chip 200 is not limited thereto. For example, the semiconductor chip 200 may be formed first, and then the wiring structure 100 may be formed. In addition, for example, the wiring structure 100 may be formed first, and then the semiconductor chip 200 may be attached.

In an exemplary embodiment of the present inventive concept, a conductive pattern may be formed in the wiring structure 100.

The third insulating layer 113 may be placed at the lowermost part of the insulating layer 110 of the wiring structure 100 and may expose the wiring pad 122 placed at the lowermost part of the wiring layer 120 of the wiring structure 100. In this case, a void R1 surrounded by the wiring pad 122 and the adhesive layer 910 may be formed inside the third insulating layer 113. In an exemplary embodiment of the present inventive concept, the void may be an empty space.

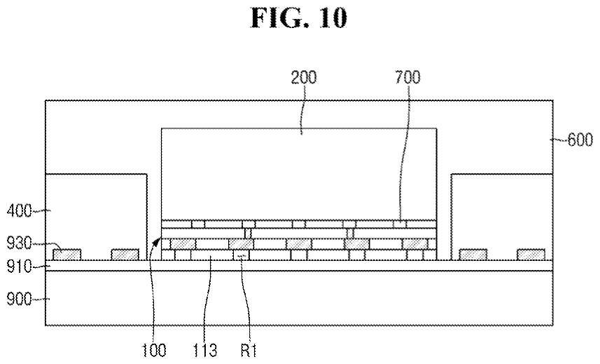

Referring to FIG. 10, the mold layer 600 is formed to cover the side surface and the upper surface of the semiconductor chip 200. The mold layer 600 may cover the side surface of the wiring structure 100, the upper surface and the side surface of the semiconductor chip 200, and the upper surface and the side surface of the support member 400.

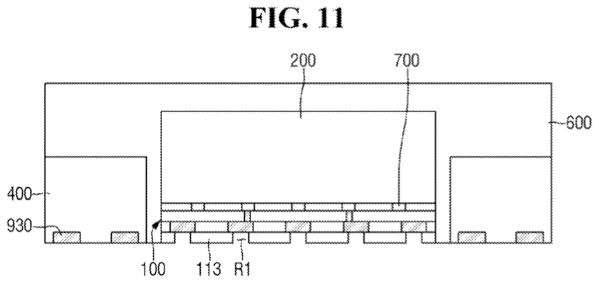

Referring to FIG. 11, the adhesive layer 910 is removed from the substrate 900. By removing the adhesive layer 910, one surface of the wiring structure 100 may be exposed. For example, the above-mentioned void R1 may form a first opening R1. For example, the conductive pattern formed in the wiring structure 100 may be exposed by the first opening R1.

By removing the adhesive layer 910, one surface of the conductive pattern 930 may be exposed. For example, the conductive pattern 930 may form a connecting pad 800 that connects the support member 400 and the dummy connecting terminal 500 to each other.

For example, when the adhesive layer 910 is a heat-treated curable adhesive tape, the adhesive layer 910 may be peeled off after being heat-treated to weaken the adhesive force. For example, when the adhesive layer 910 is an ultraviolet curable adhesive tape, the adhesive layer 910 may be peeled off after being irradiated with ultraviolet rays to weaken the adhesive force.

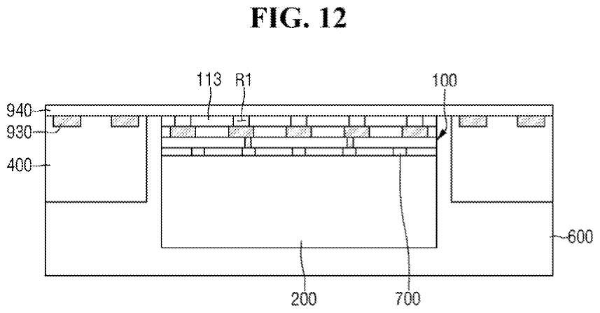

Referring to FIG. 12, the protective film 940 is formed on one surface of the support member 400 and one surface of the wiring structure 100. The protective film 940 may include an IMD (Inter Metal Dielectric) material. The protective film 940 may form the void R1 surrounded by the wiring pad 122 and the protective film 940 inside the third insulating layer 113.

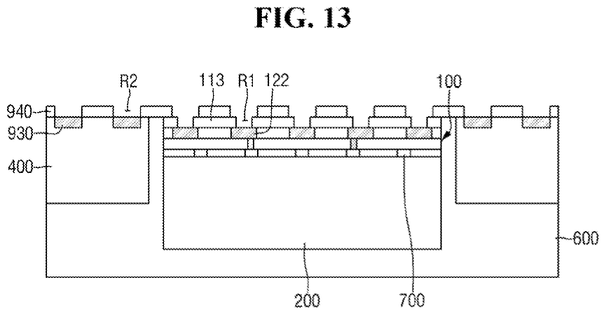

Referring to FIG. 13, a second opening R2 is formed in a region of the protective film 940 corresponding to the conductive pattern 930 and the wiring pad 122. For example, the second opening R2 may expose the conductive pattern 930 and the wiring pad 122. The second opening R2 may be formed in the region corresponding to the void R1. In this case, the second opening R2 may be formed to extend to the first opening R1 that is formed by exposing the void R1.

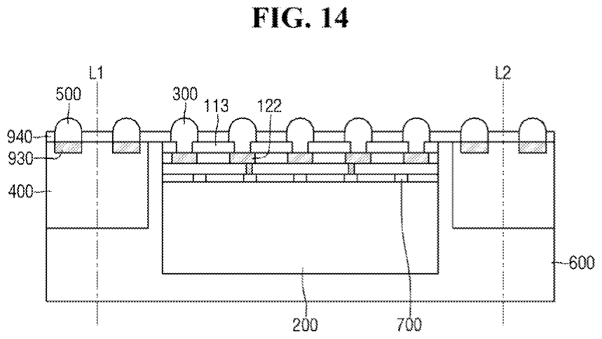

Referring to FIG. 14, the second opening R2 is filled to form the connecting terminal 300 and the dummy connecting terminal 500. For example, the second opening R2 may be filled with a conductive material. In this case, the connecting terminal 300 is formed inside the third insulating layer 113 and may come into contact with the wiring pad 122.

The conductive pattern 930 is placed inside the support member 400 and is disposed in a surface of the support member 400 that faces the protective film 940. The conductive pattern 930 is electrically connected to the dummy connecting terminal 500. The wiring pad 122 is placed inside the wiring structure 100 and is electrically connected to the connecting terminal 300. The wiring pad 122 is not electrically connected to the dummy connecting terminal 500.

Next, referring to FIGS. 14 and 5, the semiconductor package 1000 is formed by cutting along dicing lines L1 and L2.

Accordingly, a semiconductor package according to an exemplary embodiment of the present inventive concept may be provided with increased reliability by forming a dummy connecting terminal outside a connecting terminal or a solder ball connected to a wiring structure.

In addition, a semiconductor package according to an exemplary embodiment of the present inventive concept might not be easily damaged even when an external force is applied, by forming a support member outside a semiconductor chip of the semiconductor package.

While the present inventive concept has been described with reference to exemplary embodiments thereof, it will be understood by those of ordinary skill in the art that various changes in form and details may be made thereto without departing from the spirit and scope of the present inventive concept.

What is claimed is:

1. A semiconductor package comprising:
a wiring structure including at least one wiring layer;
a semiconductor chip disposed on the wiring structure and connected to the wiring structure;
a connecting terminal formed on a first surface of the wiring structure;
a support member spaced apart from the wiring structure;
a dummy connecting terminal formed on a first surface of the support member; and
a mold layer covering a side surface of the wiring structure, a first surface of the semiconductor chip, and a second surface and a side surface of the support member.

2. The semiconductor package of claim 1, wherein each of a side surface of the semiconductor chip and the side surface of the wiring structure is spaced apart from the support member and is at least partially surrounded by the support member.

3. The semiconductor package of claim 1, wherein the dummy connecting terminal and the semiconductor chip are not electrically connected to each other.

4. The semiconductor package of claim 1, wherein a thickness of a mold layer formed on the second surface of the support member is thicker than a thickness of the mold layer formed on the first surface of the semiconductor chip.

5. The semiconductor package of claim 1, wherein the at least one wiring layer includes a wiring pad including a first portion and a second portion, wherein the first portion overlaps the semiconductor chip, and the second portion does not overlap the semiconductor chip.

6. The semiconductor package of claim 5, wherein the mold layer covers a second surface, opposite to the first surface, of the wiring structure exposed by the semiconductor chip.

7. The semiconductor package of claim 1, wherein the support member includes a cavity, wherein the wiring structure is disposed in the cavity, and
wherein the mold layer fills the cavity.

8. The semiconductor package of claim 1, further comprising:
a connecting pad formed on a second surface of the semiconductor chip which faces a second surface of the wiring structure,
wherein the connecting pad and the connecting terminal are electrically connected to each other through the wiring structure.

9. The semiconductor package of claim 1, further comprising:
a connecting pad formed inside the support member and connecting the support member and the dummy connecting terminal to each other.

10. A semiconductor package comprising:
a wiring structure including at least one wiring layer;
a support member connected to a dummy connecting terminal and having a cavity, wherein the wiring structure is disposed in the cavity and is spaced apart from an inner surface of the cavity;
a semiconductor chip connected to the wiring structure and disposed in the cavity; and
a mold layer filling the cavity,
wherein the dummy connecting terminal and the semiconductor chip are not electrically connected to each other.

11. The semiconductor package of claim 10, wherein the mold layer covers a side surface of the wiring structure, an upper surface and a side surface of the semiconductor chip, and an upper surface and a side surface of the support member.

12. The semiconductor package of claim 10, wherein the dummy connecting terminal and the wiring structure are not electrically connected to each other.

13. The semiconductor package of claim 10, wherein the at least one wiring layer includes a wiring pad including a first portion and a second portion, wherein the first portion overlaps the semiconductor chip, and the second portion does not overlap the semiconductor chip, and
wherein the mold layer covers an upper surface of the wiring structure exposed by the semiconductor chip.

14. The semiconductor package of claim 10, wherein a thickness of a mold layer formed on an upper surface of the support member is thicker than a thickness of the mold layer formed on an upper surface of the semiconductor chip.

15. The semiconductor package of claim 10, further comprising:
a first connecting pad formed on a first side of the semiconductor chip which faces the wiring structure; and
a second connecting pad connecting the support member and the dummy connecting terminal to each other,
wherein the first connecting pad and the connecting terminal are electrically connected to each other through the wiring structure.

16. The semiconductor package of claim 15, wherein the dummy connecting terminal is not electrically connected to the first connecting pad.

17. A method for fabricating a semiconductor package, the method comprising:
forming a support member on a substrate, wherein an adhesive layer and a first conductive pattern are formed on the substrate;
etching at least a part of the support member to form a cavity;
forming a wiring structure and a semiconductor chip in the cavity, wherein a second conductive pattern is formed in the wiring structure, and the semiconductor chip is disposed on the wiring structure;
forming a mold layer on a side surface and an upper surface of the semiconductor chip;
removing the adhesive layer; and
forming a connecting terminal and a dummy connecting terminal on one surface of the wiring structure and one surface of the first conductive pattern, respectively, exposed by removing the adhesive layer.

18. The method for fabricating the semiconductor package of claim 17, further comprising:
forming a protective film on the support member and the wiring structure after removing the adhesive layer;
forming openings in regions of the protective film corresponding to the first and second conductive patterns; and
forming a connecting terminal and a dummy connecting terminal in the openings.

19. The method for fabricating the semiconductor package of claim 17, wherein the first conductive pattern is disposed in the support member and is electrically connected to the dummy connecting terminal,
wherein the second conductive pattern is disposed in the wiring structure and is electrically connected to the connecting terminal, and
wherein the second conductive pattern is not electrically connected to the dummy connecting terminal.

20. The method for fabricating the semiconductor package of claim 17, wherein the mold layer covers a side surface of the wiring structure, the upper surface and the side surface of the semiconductor chip, and an upper surface and a side surface of the support member.
